(19) United States
(12) Patent Application Publication
(10) Pub. No.: US 2017/0017873 A1
(43) Pub. Date: Jan. 19, 2017

(54) SUBSTRATE, WIRELESS TAG, AND ELECTRONIC DEVICE

(71) Applicant: FUJITSU LIMITED, Kawasaki-shi (JP)

(72) Inventors: Shunji Baba, Yokohama (JP); Hiroyuki Nakamoto, Kawasaki (JP)

(73) Assignee: FUJITSU LIMITED, Kawasaki-shi (JP)

(21) Appl. No.: 15/171,281

(22) Filed: Jun. 2, 2016

(30) Foreign Application Priority Data
Jul. 15, 2015 (JP) 2015-141394

(51) Int. Cl. G06K 19/077; H05K 1/02; H05K 1/18

(52) U.S. Cl. CPC G06K 19/07758; H05K 1/181; G06K 19/07773; H05K 1/028; H05K 2201/10143

(57) ABSTRACT

A substrate includes: a base member that has flexibility and insulation properties; an electrically conductive member disposed on the base member and has flexibility and electrical conductivity; an electronic component disposed over the base member and coupled to the electrically conductive member; and a covering member that has flexibility and insulation properties and that covers a portion of the base member and a portion of the electronic component, wherein the covering member has a hardness higher than a hardness of the base member, and wherein the base member is bent so as to hold the covering member inside.

### CROSS-REFERENCE TO RELATED APPLICATION

This application is based upon and claims the benefit of priority of the prior Japanese Patent Application No. 2015-141394, filed on Jul. 15, 2015, the entire contents of which are incorporated herein by reference.

### FIELD

The embodiments discussed herein are related to a substrate, a wireless tag, and an electronic device.

### BACKGROUND

There is an example of a wiring bonding element that is obtained by connecting a stretchable, flexible element to an electrical circuit board using a flexible flat cable and in which a back-side wire and a front-side wire are less easily disconnected even after repeated expansion and contraction of the flexible element since a stress that occurs at an end portion of the flexible flat cable is dispersed.

There is an example of an anisotropic electrically conductive member having a configuration that includes an elastic member having a three-layer structure obtained by sandwiching a bent-portion restricting portion between highly elastic members and in which a metal thin wire is caused to extend through the elastic member in the thickness direction of the elastic member and the portion of the metal thin wire at which it bents is restricted.

In a configuration in which an electronic component is mounted on a flexible base member and a flexible electronic component mounted on the base member is connected to this electronic component, when the base member is bent, the electrically conductive member may be acutely bent at a portion at which the base member is bent and may be disconnected.

The followings are reference documents.
[Document 1] Japanese Laid-open Patent Publication No. 2012-113851 and
[Document 2] Japanese Laid-open Patent Publication No. 2008-218185.

### SUMMARY

According to an aspect of the invention, a substrate includes: a base member that has flexibility and insulation properties; an electrically conductive member disposed on the base member and has flexibility and electrical conductivity; an electronic component disposed over the base member and coupled to the electrically conductive member; and a covering member that has flexibility and insulation properties and that covers a portion of the base member and a portion of the electronic component, wherein the covering member has a hardness higher than a hardness of the base member, and wherein the base member is bent so as to hold the covering member inside.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of a substrate according to a first embodiment in an unfolded state;

FIG. 2 is a perspective view of an electronic device according to the first embodiment;

FIG. 3 is a perspective view of the electronic device according to the first embodiment;

FIG. 4 is a cross-sectional view of the electronic device according to the first embodiment that is in an unbent state;

FIG. 5 is a cross-sectional view of the electronic device according to the first embodiment that is in a bent state;

FIG. 6 is a cross-sectional view of an electronic device according to a first comparative example that is in a bent state;

FIG. 7 is a cross-sectional view of an electronic device according to a second embodiment that is in an unbent state;

FIG. 8 is a perspective view of a substrate according to a third embodiment in an unfolded state;

FIG. 9 is a perspective view of an electronic device according to the third embodiment;

FIG. 10 is a perspective view of the electronic device according to the third embodiment;

FIG. 11 is a perspective view of a substrate according to a fourth embodiment in an unfolded state;

FIG. 12 is a perspective view of a wireless tag (electronic device) according to the fourth embodiment; and

FIG. 13 is a perspective view of the wireless tag (electronic device) according to the fourth embodiment.

### DESCRIPTION OF EMBODIMENTS

Referring now to the drawings, a first embodiment is described in detail.

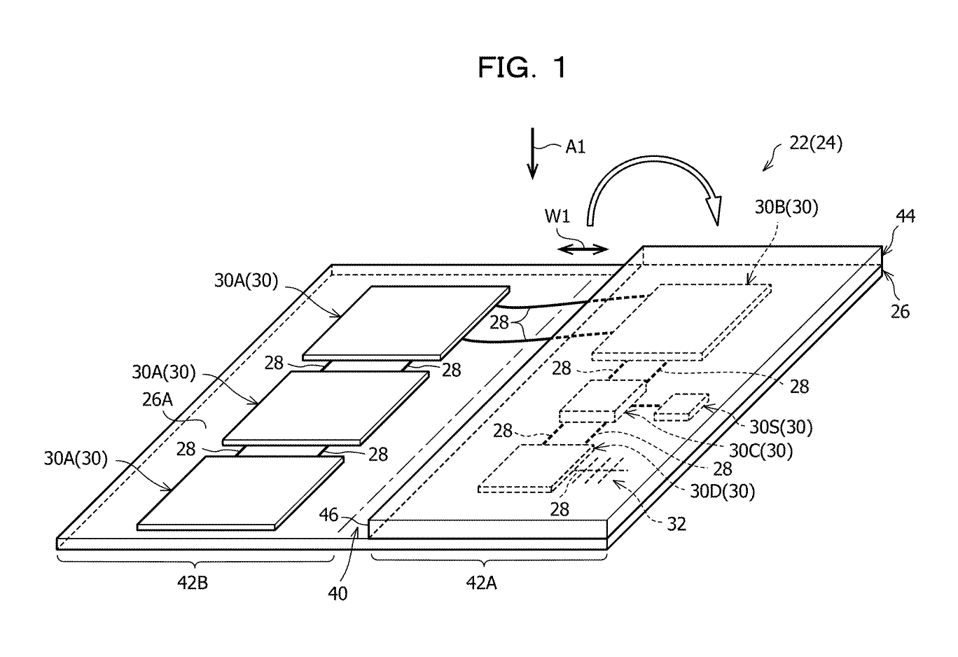

As illustrated in FIG. 1, a substrate 22 according to a first embodiment includes a plate-shaped base member 26. The base member 26 is made of a material having flexibility and insulation properties. A specific example of a material of the base member 26 is silicone but the material is not limited to silicone. In this embodiment, the base member 26 is rectangular when viewed in a plan (when viewed in a direction of arrow A1 in FIG. 1).

A first surface (upper surface in FIG. 1) of the base member 26 is a component onboard surface 26A. Conduction patterns 28 are formed on the component onboard surface 26A. The conduction patterns 28 are examples of an electrically conductive member. The conduction patterns 28 are made of a material having flexibility and electrical conductivity. Specific examples of such a material include an electrically conductive member obtained by dispersing electrically conductive metal particles in rubber. The rubber in the electrically conductive member functions as a binder, and thus the conduction patterns 28 have elasticity (flexibility). The volume of the electrically conductive member is preserved before and after the electrically conductive member is deformed. Thus, when, for example, the electrically conductive member expands in a specific direction, the electrically conductive member contracts in a direction perpendicular to the direction in which the electrically conductive member expands. When the electrically conductive member contracts in the direction perpendicular to the direction in which the electrically conductive member expands, the electrical conductivity metal particles move close to one another in the direction in which electrically conductive member contracts, whereby the electrically conductive member may retain its electrical conductivity.

In this embodiment, multiple electronic components 30 are mounted on the base member 26. FIG. 1 illustrates power supply units 30A, an electricity storage unit 30B, a controlling unit 30C, a communication unit 30D, and a sensor unit 30S as examples of the electronic components 30. The power supply units 30A and the electricity storage unit 30B are electrically connected together using the conduction patterns 28. The electricity storage unit 30B and the controlling unit 30C are electrically connected together using the conduction patterns 28. The controlling unit 30C and the communication unit 30D are electrically connected together using the conduction patterns 28. The controlling unit 30C and the sensor unit 30S are electrically connected together using the conduction patterns 28. For example, power of the power supply units 30A is accumulated in the electricity storage unit 30B and the controlling unit 30C is driven by being supplied with the power from the electricity storage unit 30B. The sensor unit 30S is a sensor that detects physical properties such as the position of an electronic device 24 or the circumstances of the electronic device 24 and transmits detected information to the controlling unit 30C. The electronic components 30 are examples of onboard components.

An antenna 32 is connected to the communication unit 30D. In this embodiment, at least one of the conduction patterns 28 constitutes the antenna 32. The communication unit 30D transmits and receives signals to and from external devices through the antenna 32.

As illustrated in FIG. 1, the base member 26 has a fold portion 40 at a middle portion in the widthwise direction (direction of arrow W1). In this embodiment, the electricity storage unit 30B, the controlling unit 30C, the communication unit 30D, and the sensor unit 30S are disposed in a first area 42A (a right area in FIG. 1), defined by the fold portion 40, and the power supply units 30A are disposed in a second area 42B, defined by the fold portion 40.

A covering member 44 is disposed in the first area 42A. The covering member 44 is made of a material having insulation properties and flexibility. In a plan view, the covering member 44 is disposed so as to have such a shape as to cover the electricity storage unit 30B, the controlling unit 30C, the communication unit 30D, and the sensor unit 30S.

In this embodiment, the covering member 44 is rectangular when viewed in the thickness direction (direction of arrow A1). When viewed in the direction of arrow A1, three of the four sides of the covering member 44 overlap the sides of the base member 26 but the remaining side (edge portion 46) is disposed on the inner side of the base member 26. The base member 26 is folded along the edge portion 46, so that the fold portion 40 is formed.

In the first embodiment, the hardness of the entirety of the covering member 44 is higher than the hardness of the base member 26. The “hardness” here is, for example, a durometer hardness according to JIS K6253. The wording “the hardness is high or low” means that the value obtained by expressing the “hardness” with numbers by a specific measuring method is large or small. For example, the durometer hardness of the covering member 44 is approximately 70 (or may be higher than 70) whereas the durometer hardness of the base member 26 is approximately 40.

In the state illustrated in FIG. 1, the conduction patterns 28 disposed in part of the second area 42B and the fold portion 40 are exposed over the surface of the base member 26.

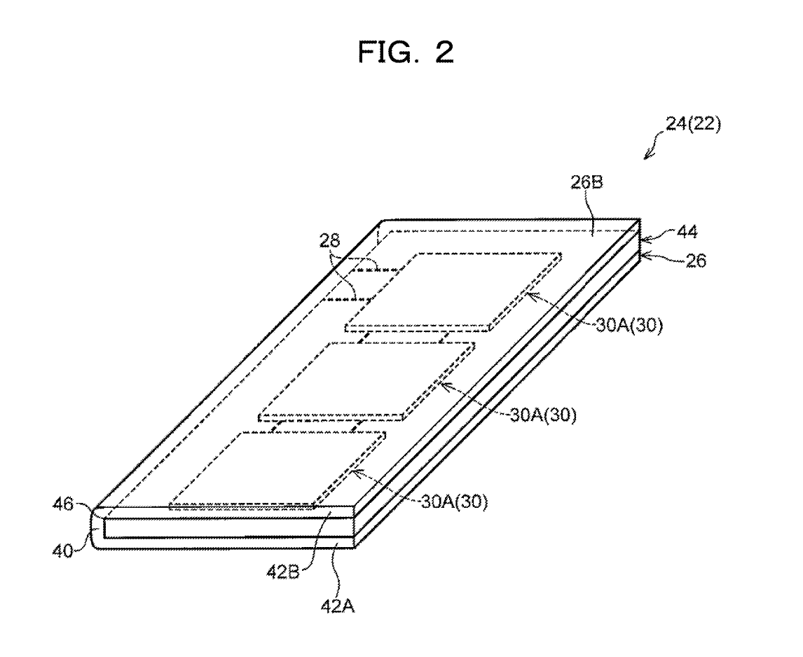

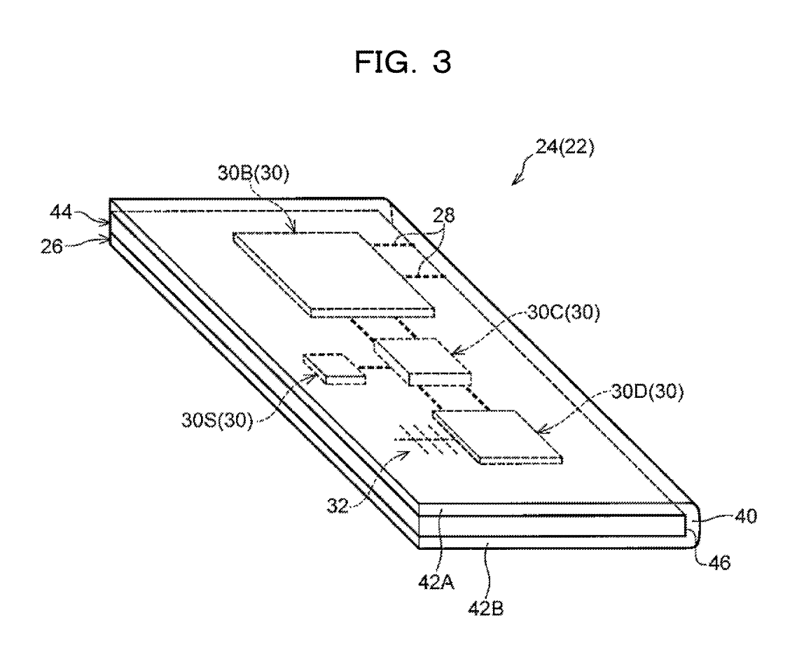

The electronic device 24 according to this embodiment has a configuration in which the base member 26 of the substrate 22 is folded at the fold portion 40 along the edge portion 46 so as to hold the covering member 44 between the upper and lower portions of the base member 26 as illustrated in FIG. 2 and FIG. 3.

For example, the electronic device 24 is disposed at a predetermined position under the ground or in a building and used as a device that transmits position information. At the position at which the electronic device 24 is to be disposed, the surface on which the electronic device 24 is placed may be curved or uneven. Even when the substrate 22 has a configuration in which the base member 26 is unbent as described above (configuration illustrated in FIG. 1), the substrate 22 may be used as the electronic device 24. Alternatively, the electronic device 24 may be used in a form of folded at a predetermined portion or in a rolled form.

Now, operations of this embodiment are described.

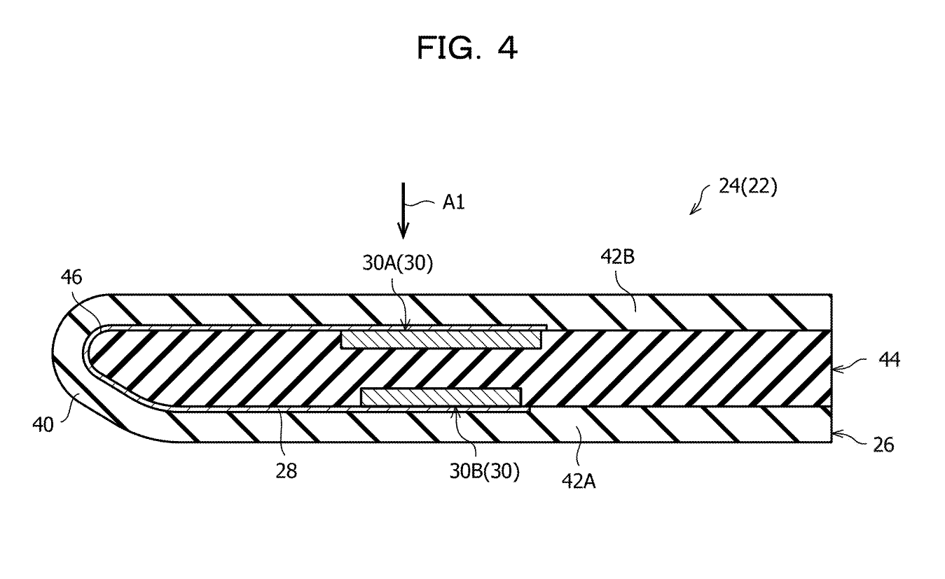

As illustrated in FIG. 1, the electricity storage unit 30B, the controlling unit 30C, the communication unit 30D, and the sensor unit 30S, which are mounted on the base member 26 of the substrate 22, are covered with the covering member 44. As illustrated in FIG. 2 and FIG. 3, the base member 26 of the electronic device 24 is then folded at the fold portion 40 along the edge portion 46 so as to hold the covering member 44 inside and so as to be disposed on both sides of the covering member 44. As also illustrated in FIG. 4, folding the base member 26 in this manner easily achieves a configuration in which various types of electronic components 30 are superposed one on top of another in two layers.

Moreover, as understood from FIG. 4, multiple electronic components 30 (one power supply unit 30A and the electricity storage unit 30B in FIG. 4) disposed on both sides of the covering member 44 are superposed one on top of the other in the thickness direction of the covering member 44 (direction of arrow A1). By disposing multiple electronic components 30 in a superposed manner, multiple types of electronic components 30 are allowed to be compactly disposed within a small range (range obtained by folding the base member 26 in half).

The covering member 44 is interposed between the electronic components 30 superposed one on top of the other. This configuration thus lessens the likelihood of contact between the electronic components 30 superposed in a plan view and thus lessens the likelihood of displacement or deformation of the electronic components 30 that could occur due to the contact between the electronic components 30.

As illustrated in FIG. 4, if the covering member 44 is thin and when the base member 26 is folded along the edge portion 46, the covering member 44 may be deformed into a form of a taper (wedge shape) toward the edge portion 46. Particularly, when the width of the first area 42A and the width of the second area 42B differ from each other (the width of the second area 42B is larger than the width of the first area 42A in the example illustrated in FIG. 4), the covering member 44 is more likely to be deformed into a form of a taper toward the edge portion 46. When the edge portion 46 has a low hardness, the edge portion 46 may be formed into an acutely sharp shape. In this case, the base member 26 and the conduction pattern 28 folded so as to surround the edge portion 46 is formed into an acutely bent shape. Specifically, at portions of the base member 26 and the conduction pattern 28 bent so as to surround the edge portion 46, the base member 26 and the conduction pattern 28 have a large curvature (or have a small radius of curvature).

In this embodiment, on the other hand, the hardness of the covering member 44 (including the edge portion 46) is higher than the hardness of the base member 26. As illustrated in FIG. 4, the likelihood of deformation of the edge portion 46 into a sharp shape is thus lessened. Thus, the base member 26 and the conduction pattern 28 folded along the edge portion 46 are also gently bent along the edge portion 46. Specifically, at portions of the base member 26 and the conduction pattern 28 that surround the edge portion 46, the base member 26 and the conduction pattern 28 have a small curvature (or have a large radius of curvature).

As described above, this embodiment lessens the likelihood that the curvature of the base member 26 and the conduction pattern 28 bent along the edge portion 46 become excessively large. Since the conduction pattern 28 is not acutely bent, the likelihood of disconnection of the conduction patterns 28 is lessened.

As described above, the electronic device 24 is installed at, for example, a predetermined portion under the ground or in a building. When the portion at which the electronic device 24 is flat, the base member 26 of the electronic device 24 remains flat, as illustrated in FIG. 4.

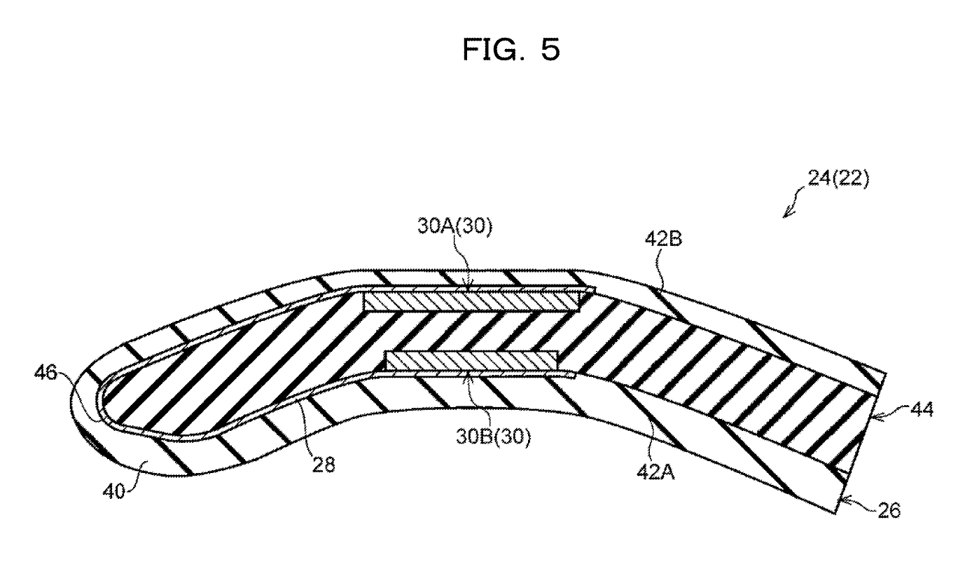

In this embodiment, the hardness of the covering member 44 is higher than the hardness of the base member 26, but the covering member 44 has flexibility. The base member 26 also has flexibility. Even when the portion at which the electronic device 24 is installed is three-dimensionally bent as in the case of the spherical surface, the electronic device 24 is allowed to be installed at the bent portion by being bent so as to follow the shape of the bent portion. In the example illustrated in FIG. 5, the entirety of the electronic device 24 is bent in such a manner that the first area 42A is disposed inward.

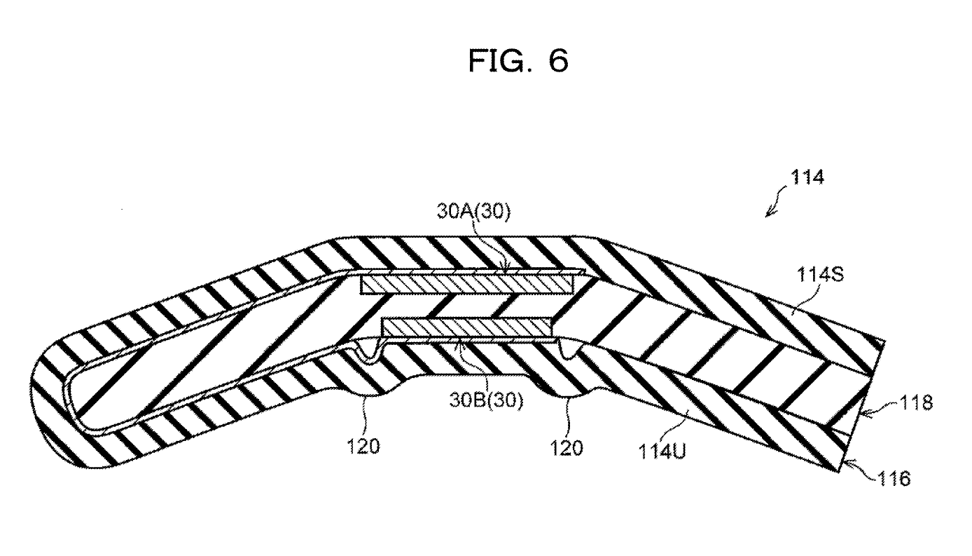

Here, FIG. 6 illustrates an electronic device 114 according to a first comparative example. In the electronic device 114 according to the first comparative example, the hardness of a base member 116 is higher than the hardness of a covering member 118.

Even the electronic device 114 according to the first comparative example may be entirely bent as long as the base member 116, the conduction patterns 28, and the covering member 118 have flexibility. In the electronic device 114 according to the first comparative example, however, the hardness of the base member 116 is higher than the hardness of the covering member 118. In the bent electronic device 114, when the radius of curvature of a bent inner side 114U and the radius of curvature of a bent outer side 114S differ from each other, the base member 116 and the conduction pattern 28 may fail to follow these different radii of curvature. Thus, the base member 116 and the conduction pattern 28 disposed on the bent inner side 114U may have creases 120. The occurrence of such creases 120 renders the bent inner surface of the electronic device 114 unsuitable for being used as an installation surface. Moreover, in the configuration where at least one of the conduction patterns 28 is used as an antenna, the conduction pattern 28 may fail to fulfill its intended function as an antenna since the antenna has creases 120.

In the electronic device 24 according to this embodiment, the base member 26, the conduction pattern 28, and the covering member 44 have flexibility and the entirety of the electronic device 24 is allowed to be bent as illustrated in FIG. 5. Thus, the electronic device 24 is allowed to be bent (see FIG. 5) or to expand or contract in accordance with the shape of the portion at which the electronic device 24 is installed.

In the electronic device 24 according to this embodiment, the hardness of the base member 26 is lower than the hardness of the covering member 44. When a bent inner side 24U and a bent outer side 24S of the electronic device 24 have different radii of curvature, the base member 26 appropriately contracts so as to follow the bent shape. Since the base member 26 and the conduction pattern 28 do not have creases 120 (see FIG. 6), the bent inner surface may be easily used as an installation surface. Moreover, in the configuration where at least one of the conduction patterns 28 is used as the antenna 32, the conduction pattern 28 may fulfill its intended function as an antenna since the antenna 32 has no creases 120.

In the first embodiment, the “hardness” of the entirety of the covering member 44 is higher than the “hardness” of the base member 26. Specifically, the covering member 44 solely achieves a configuration in which the edge portion 46 is harder than the base member 26, whereby the configuration is simple.

Subsequently, a second embodiment is described. In the second embodiment, components or the like that are the same as those according to the first embodiment are denoted with the same reference symbols and are not described in detail.

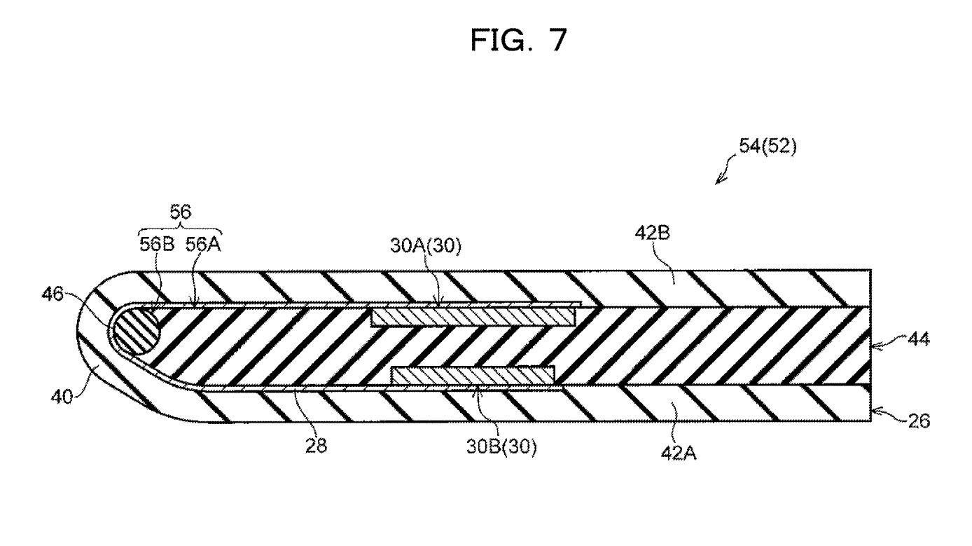

As illustrated in FIG. 7, a substrate 52 or an electronic device 54 according to the second embodiment includes a covering member 56, which includes a covering member body 56A and a hard member 56B. The hard member 56B is disposed at the edge portion 46 of the covering member 56. The hardness of the hard member 56B is higher than the hardness of the base member 26.

In the example illustrated in FIG. 7, the hard member 56B is cylindrical and is made of rubber harder than the base member 26. The hard member 56B may be integrally joined to the covering member body 56A by a method such as bonding or welding or may be interposed between the covering member body 56A and the base member 26 (at a portion at which the base member 26 is folded) when, for example, the base member 26 is folded along the edge portion 46.

In the second embodiment, the configuration in which the edge portion 46 is harder than the base member 26 is thus achieved by disposing the hard member 56B at the edge portion 46 of the covering member 56. The “hardness” of the covering member body 56A may be equivalent to or lower than the “hardness” of the base member 26. Specifically, the allowable range of the “hardness” of the covering member body 56A is wide. For example, setting the “hardness” of the covering member body 56A low allows the substrate 52 or the electronic device 54 to have an easily deformable configuration.

A third embodiment is described now. In the third embodiment, components or the like that are the same as those according to the first embodiment are denoted with the same symbols and are not described in detail.

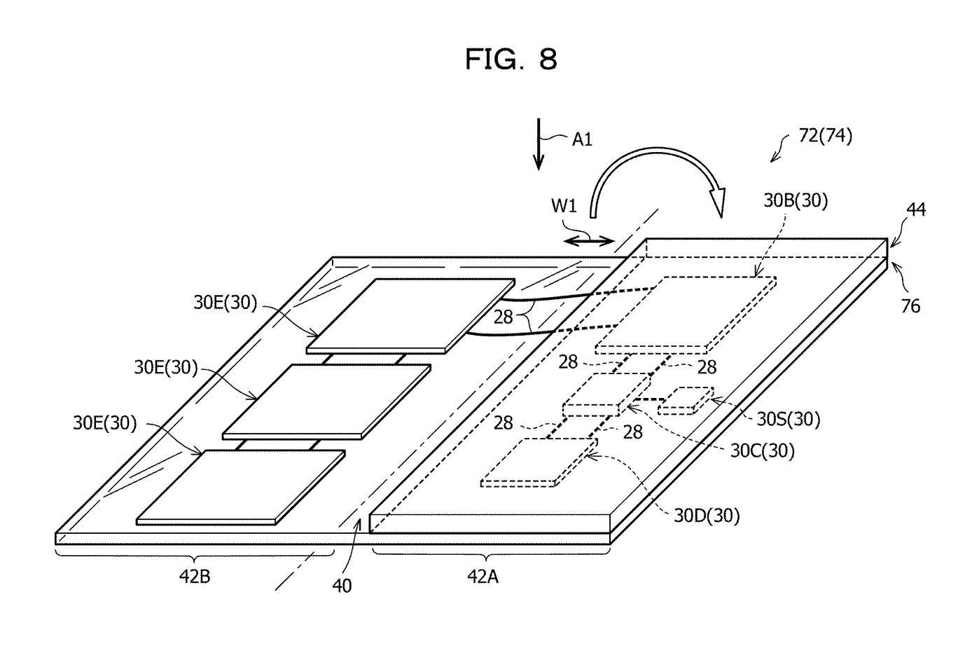

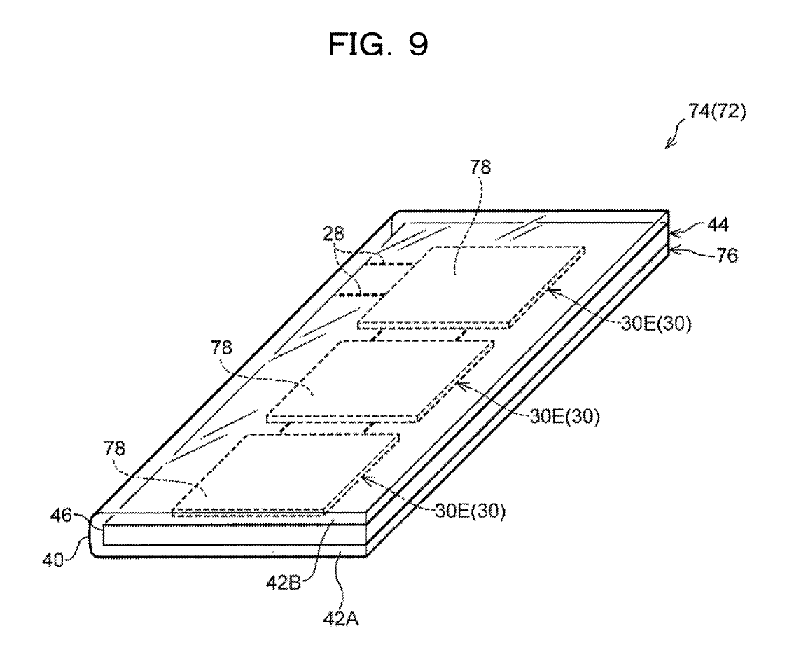

As illustrated in FIG. 8 to FIG. 10, instead of the power supply units 30A of the electronic device 24 according to the first embodiment, solar cells 30E are disposed on a substrate 72 (electronic device 74) according to the third embodiment. As illustrated in FIG. 9, the solar cells 30E are disposed in a second area 42B in such a manner that light receiving portions 78 of the solar cells 30E are directed toward a base member 76. The solar cells 30E according to the third embodiment are examples of electronic components and examples of the power supply units 30A (see FIG. 1). In addition, the solar cells 30E according to the third embodiment are examples of power generating units.

The base member 76 according to the third embodiment is transparent. The wording “the base member 76 is transparent” here means that the base member 76 allows light to pass therethrough to such a degree that each solar cell 30E is capable of generating power in response to an incidence of the light on the light receiving portion 78 of the solar cell 30E.

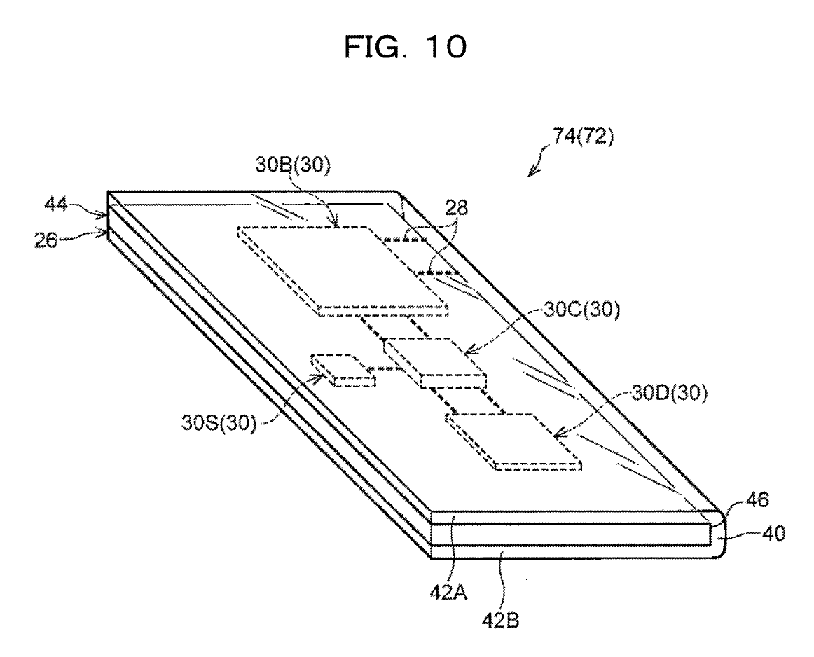

As illustrated in FIG. 9 and FIG. 10, in the electronic device 74, the base member 76 has a configuration in which it is bent at the fold portion 40 so as to hold the covering member 44. Thus, the light receiving portion 78 of each solar cell 30E faces to the outer side of the electronic device 74 (upward in FIG. 9).

In the third embodiment, when the solar cells 30E generate power, the solar cells 30E may supply power to the other electronic components 30.

Since the base member 76 according to the third embodiment is transparent, the external light may be reliably applied to the light receiving portions 78.

In the third embodiment, the base member 76 does not have to be entirely transparent in view of an application of light to the light receiving portions 78. The base member 76 suffices as long as portions of the base member 76 facing the light receiving portions 78 are transparent.

The third embodiment may include the covering member 56 according to the second embodiment instead of the covering member 44.

In each of the above-described embodiment, multiple electronic components 30 are mounted on the base member 26. The covering member 44 or 56 covers the multiple electronic components 30. In other words, the multiple electronic components 30 are covered with the common covering member 44 or 56. This configuration includes fewer components than in the case where the electronic components 30 are covered with respective covering members.

By connecting the multiple electronic components 30 together with the conduction patterns 28, a configuration that is designed for multiple electronic components 30 and that exerts a predetermined function is achieved.

At least one of the conduction patterns 28 constitutes the antenna 32. The antenna 32 transmits or receives radio waves to or from external devices to exchange information with the external devices. Since the antenna 32 is constituted with at least one of the conduction patterns 28, no component is added to serve as an antenna and thus the number of components does not increase.

In each embodiment, some of the multiple electronic components 30 are the power supply units 30A. The power supply units 30A supply power to the other electronic components 30 to drive these electronic components 30.

The power supply units 30A may be either primary cells or secondary cells. In either case, if the power supply units 30A include power generating units (including the solar cells 30E according to the third embodiment), they may generate power by themselves, thereby dispensing with an exchange of the primary cells or charging of the secondary cells. Examples of the power generating units include, besides the solar cells 30E, a member (vibration powered generator) that vibrates a mass body (mass) with vibrations exerted on the electronic device to generate power using the vibrations of the mass body that vibrate the mass body and a member that puts a pressure on a piezoelectric element with vibrations of the electronic device to generate power.

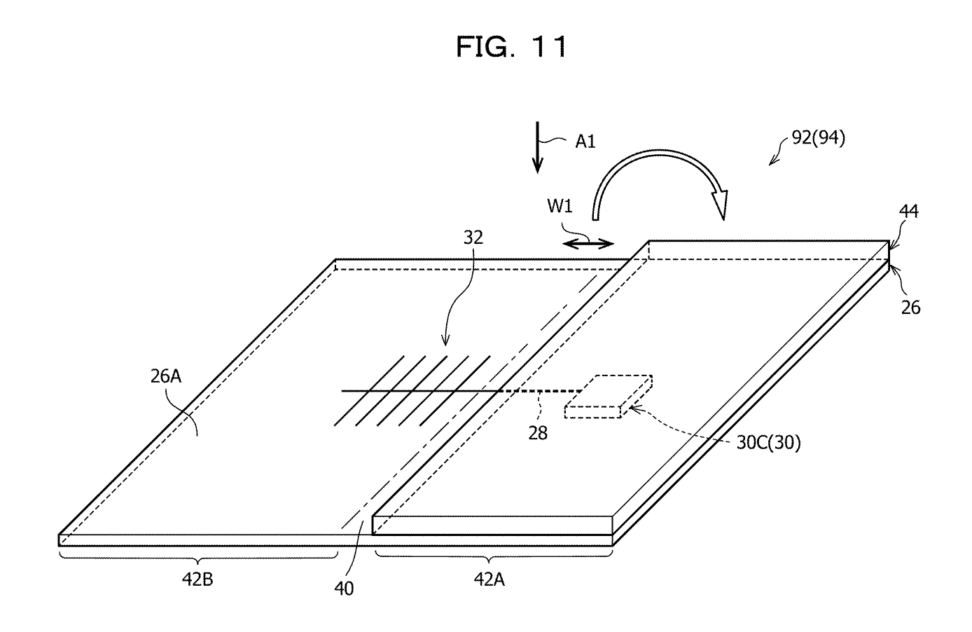

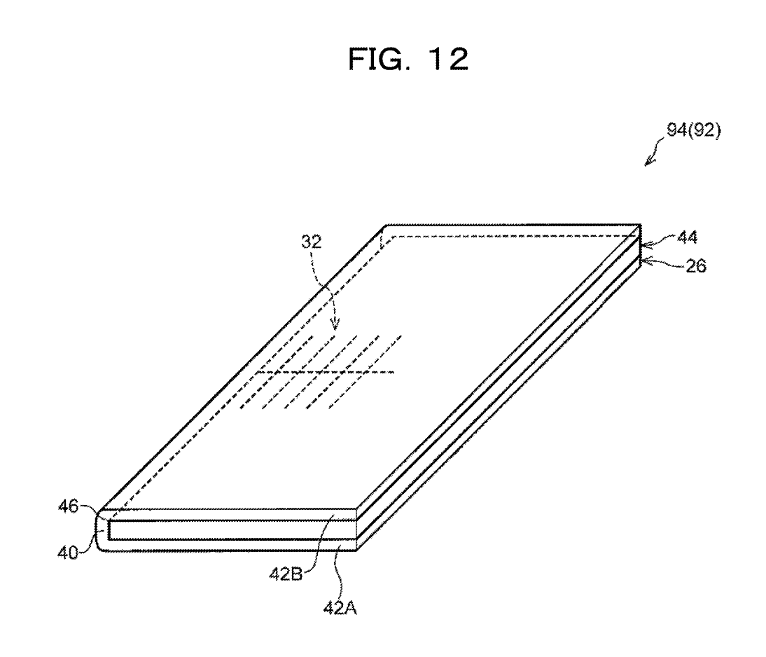

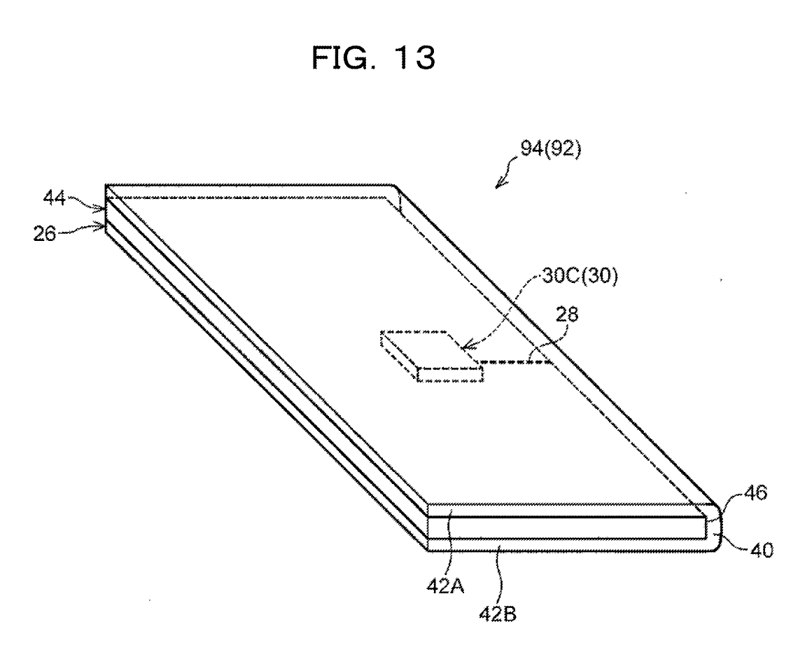

For example, the electronic device may have a configuration that includes an antenna 32 and only one electronic component 30. As a fourth embodiment, FIG. 11 to FIG. 13 illustrate a substrate 92 (wireless tag 94) that includes only one electronic component 30, as described above. Also in the fourth embodiment, components or the like that are the same as those according to the first embodiment are denoted with the same reference symbols and not described in detail.

The wireless tag 94 according to the fourth embodiment includes a controlling unit 30C as an example of the electronic component 30. Thus, the wireless tag 94 may perform operations such as wirelessly write or read information on or from a storage area in the controlling unit 30C through the antenna 32 with external devices. If the wireless tag 94 has such a configuration that the controlling unit 30C is driven by radio waves received from external devices, the controlling unit 30C dispenses with an energy source. Here, the wireless tag 94 may be referred to as a radio frequency identification (RFID) element. The wireless tag 94 according to the fourth embodiment may be regarded as an example of the electronic device. Particularly, the wireless tag 94 is an example of an electronic device including one electronic component 30.

The wireless tag 94, however, may have a configuration that includes multiple electronic components 30. For example, the wireless tag 94 may include the power supply unit 30A and may transmit radio waves through the antenna 32 while being provided with power from the power supply unit 30A.

The above-described configuration in which the base member 26 or 76 of the substrate 22, 52, 72, or 92 is folded along the edge portion 46 and is disposed on both sides of the covering member 44 is described as an example of the electronic device. Here, the configuration in which the base member 26 or 76 is not folded along the edge portion 46 is also usable as an electronic device.

Examples of the electronic device are not limited to the devices installed at predetermined positions under the ground or in a building as described above. For example, the electronic device may be part of an ornament or equipment attached to clothes or worn by persons. More specifically, examples of the electronic device include a device that detects the position, movement, or circumstances of a wearer and transmits input information to other electronic devices or the like. Such an electronic device may achieve an integrated configuration as a while by allowing an electronic component functioning as a sensor and an electronic component that transmits and receives electronic waves to be mounted on a single base member.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A substrate comprising:
a base member that has flexibility and insulation properties;
an electrically conductive member disposed on the base member and has flexibility and electrical conductivity;
an electronic component disposed over the base member and coupled to the electrically conductive member; and
a covering member that has flexibility and insulation properties and that covers a portion of the base member and a portion of the electronic component,
wherein the covering member has a hardness higher than a hardness of the base member, and
wherein the base member is bent so as to hold the covering member inside.

2. The substrate according to claim 1, wherein
at a portion of the base member at which the base member is bent, the hardness of the covering member is higher than the hardness of the base member.

3. The substrate according to claim 1, wherein
the covering member includes
a body member, and
a hard member that is disposed at an edge portion of the body member and has a hardness higher than the hardness of the base member.

4. The substrate according to claim 1, further comprising:
a plurality of the electronic components disposed over the base member and coupled to the electrically conductive member,
wherein the covering member covers at least one of the plurality of electronic components.

5. The substrate according to claim 4, wherein
the electrically conductive member is coupled to the plurality of electronic components.

6. The substrate according to claim 4, wherein
at least one of the plurality of electronic components is a power generating unit.

7. The substrate according to claim 6, wherein
the power generating unit is a solar cell.

8. The substrate according to claim 7, wherein
a portion of the base member that faces a light receiving portion of the solar cell is made of a material that transmits light.

9. The substrate according to claim 1, wherein
a portion of the electrically conductive member constitutes an antenna.

10. A wireless tag comprising:
a base member that has flexibility and insulation properties;
an antenna disposed on the base member and has flexibility and electrical conductivity;
an electronic component disposed over the base member and coupled to the antenna; and
a covering member that has flexibility and insulation properties and that covers a portion of the base member and a portion of the electronic component,
wherein the covering member has a hardness higher than a hardness of the base member, and
wherein the base member is bent so as to hold the covering member inside.

11. An electronic device comprising:
a base member that has flexibility and insulation properties;
an electrically conductive member disposed on the base member and that has flexibility and electrical conductivity;
an electronic component disposed over the base member and coupled to the electrically conductive member; and
a covering member that has flexibility and insulation properties and that covers a portion of the base member and a portion of the electronic component,
wherein the covering member has a hardness higher than a hardness of the base member, and
wherein the base member is bent so as to hold the covering member inside.

12. The electronic device according to claim 11, wherein
the electronic component is one of a plurality of electronic components disposed over two sides of the covering member.

13. The electronic device according to claim 12, wherein
the plurality of electronic components are superposed one on top of another in a thickness direction of the covering member.

14. The electronic device according to claim 13, wherein
the covering member is disposed between the plurality of electronic components that are superposed one on top of another.
